(19) United States
(12) Patent Application Publication
(10) Pub. No.: US 2016/0268972 A1
(43) Pub. Date: Sep. 15, 2016

(54) WIRELESS COMMUNICATION DEVICE

(71) Applicant: KABUSHIKI KAISHA TOSHIBA, Tokyo (JP)

(72) Inventor: Yuki FUJIMURA, Ota Tokyo (JP)

(21) Appl. No.: 14/839,875

(22) Filed: Aug. 28, 2015

(30) Foreign Application Priority Data
Mar. 13, 2015 (JP) 2015-051338

(51) Int. Cl. H03F 1/02; H03F 3/21; H03F 3/19; H03F 1/32

(52) U.S. Cl. CPC H03F 1/0205; H03F 1/3241; H03F 3/21; H03F 3/19; H03F 2200/451; H03F 2201/3233; H03F 2201/3215

(57) ABSTRACT

A wireless communication device includes a table, a correction unit, a digital-to-analog converter (DAC), a power amplifier, an analog-to-digital converter (ADC), a calculation unit, and an update unit. The table stores distortion correction coefficients, each corresponding to a different amplitude level of a transmission signal. The correction unit corrects the transmission signal based on the distortion correction coefficient. The DAC converts the corrected transmission signal into an analog signal. The power amplifier amplifies the analog signal. The ADC converts the amplified signal into a digital signal. The calculation unit calculates a distortion correction coefficient candidate based on the transmission signal and the digital signal. The update unit updates the distortion correction coefficient stored in the table based on the distortion correction coefficient candidate, so long as the number of times the transmission signal is input to the correction unit is not greater than a threshold.

### CROSS-REFERENCE TO RELATED APPLICATION

This application is based upon and claims the benefit of priority from Japanese Patent Application No. 2015-051338, filed Mar. 13, 2015, the entire contents of which are incorporated herein by reference.

### FIELD

Embodiments described herein relate generally to a wireless communication device.

### BACKGROUND

Recently, in the field of wireless communication, a technology called digital pre-distortion (DPD) has been developed to compensate for the distortion of a power amplifier output based on the reverse characteristics of the gain characteristics of the power amplifier. By compensating for the distortion of the power amplifier output through the DPD, it is possible to achieve a linear output even in a nonlinear area of the power amplifier, and it is possible to increase the power conversion efficiency of the power amplifier.

The reverse characteristics of the power amplifier are calculated by comparing a digital signal obtained by performing an analog-to-digital conversion on the power amplifier output with an original digital signal. Since the gain characteristics of the power amplifier are changed depending on temperature, a process of updating the reverse characteristics is continuously performed in a wireless communication device of the related art. However, when the updating process is continuously performed, there is a problem in that the power consumption of the wireless communication device increases.

### DESCRIPTION OF THE DRAWINGS

FIG. 1 is a diagram showing a wireless communication device according to a first embodiment.

FIG. 2 is a diagram showing an example of a distortion correction coefficient table.

FIG. 3 is a diagram showing the gain characteristics of a power amplifier.

FIG. 4 is a diagram showing an address completion determining unit of FIG. 1.

FIG. 5 is a diagram showing an example of a counter.

FIG. 6 is a diagram showing an example of a completion bit.

FIG. 7 is a diagram for describing the operation of the wireless communication device in FIG. 1.

FIG. 8 is a diagram for describing a method of setting a completion bit according to a second embodiment.

FIG. 9 is a diagram for describing a method of setting a threshold according to a third embodiment.

FIG. 10 is a diagram showing examples of a table, a counter and a completion bit at the time of ending packet transmission according to a fourth embodiment.

### DETAILED DESCRIPTION

Embodiments provide a wireless communication device with lower power consumption in which output distortion is compensated for through DPD.

In general, according to one embodiment, a wireless communication device includes a memory that contains a table that stores a plurality of distortion correction coefficients which are respectively set for different amplitude levels of an input transmission signal, a correction unit to which the input transmission signal and one of the distortion correction coefficients are input, the correction unit configured to generate a corrected transmission signal based on the input transmission signal and one of the distortion correction coefficients that are input thereto, a digital-to-analog converter connected to the correction unit to generate an analog signal from the corrected transmission signal, a power amplifier configured to amplify the analog signal, an analog-to-digital converter connected to the power amplifier to convert the amplified signal into a digital signal, a calculation unit configured to calculate a distortion correction coefficient candidate based on the input transmission signal and the digital signal, and an update unit configured to update the distortion correction coefficient stored in the table based on the distortion correction coefficient candidate. The update unit updates the distortion correction coefficient stored in the table when the number of times the transmission signal is input to the correction unit is equal to or less than a predetermined threshold, and does not update the distortion correction coefficient when the number of times the transmission signal is input to the correction unit is greater than the threshold.

Hereinafter, example embodiments are described with reference to the drawings.

### First Embodiment

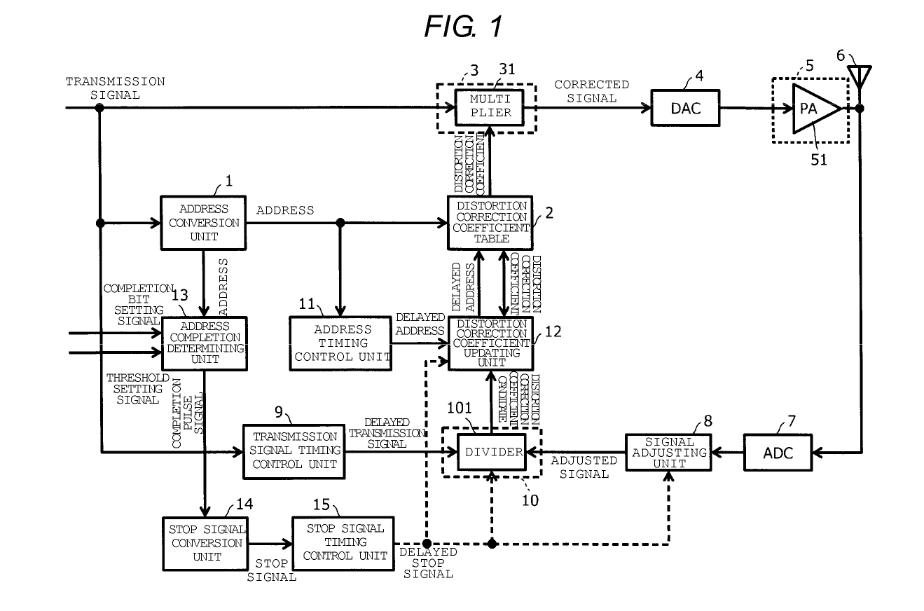

A wireless communication device according to a first embodiment is described with reference to FIGS. 1 to 7. The wireless communication device according to the present embodiment receives a transmission signal, which is a digital signal, as an input, and transmits a radio signal corresponding to the transmission signal.

FIG. 1 is a diagram showing the wireless communication device according to the present embodiment. As shown in FIG. 1, the wireless communication device includes the following hardware elements: an address conversion unit 1, a distortion correction coefficient table 2, a correction unit 3, a digital-to-analog converter 4, an amplification circuit 5, an antenna 6, an analog-to-digital converter 7, a signal adjusting unit 8, a transmission signal timing control unit 9, a distortion correction coefficient candidate calculating unit 10, an address timing control unit 11, a distortion correction coefficient updating unit 12, an address completion determining unit 13, a stop signal conversion unit 14, and a stop signal timing control unit 15.

The address conversion unit 1 (hereinafter, referred to as a “conversion unit 1”) receives the transmission signal as an input, and calculates the level of the transmission signal. The level refers to amplitude or power. The conversion unit 1 converts the calculated level into a corresponding address. The address refers to an address of a memory containing the distortion correction coefficient table 2. The conversion unit 1 outputs the converted address.

The distortion correction coefficient table 2 (hereinafter, referred to as a “table 2”) stores a plurality of distortion correction coefficients set for the levels of the transmission signal. The distortion correction coefficient is a coefficient for correcting the transmission signal, and is set so as to be proportional to the reverse characteristics of the amplification circuit 5, to be described below. Design values are preferably stored as initial values of the distortion correction coefficients in the table 2.

The table 2 is stored in the memory, and the levels of the transmission signal are respectively associated with the addresses of the memory. When the address is received from the conversion unit 1 as an input, the table 2 outputs the distortion correction coefficient set for the level corresponding to the received address.

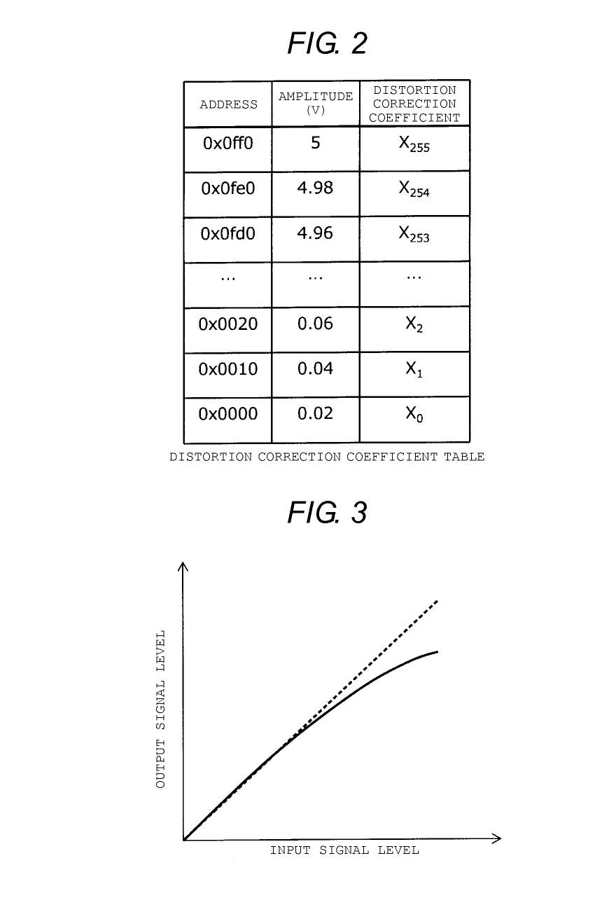

FIG. 2 is a diagram showing an example of the table 2. In the example of FIG. 2, the distortion correction coefficients are respectively set for the amplitudes of the transmission signals, and the addresses are associated with the levels of the transmission signal in ascending order of the amplitude. When the amplitude of the transmission signal is 0.06 (V), the conversion unit 1 outputs an address of 0x0020, and the table 2 of FIG. 2 outputs a distortion correction coefficient X₂ (set for the amplitude of 0.06 (V)) corresponding to the address of 0x0020.

The distortion correction coefficients can be respectively set for the powers of the transmission signal, and the addresses are then associated with the levels of the transmission signal in descending order of the power. Distortion correction coefficients for correcting I components of the transmission signal and distortion correction coefficients for correcting Q components thereof may be stored in the table 2.

The correction unit 3 receives the transmission signal and the distortion correction coefficient as inputs. The correction unit 3 corrects the transmission signal based on the distortion correction coefficient. Specifically, the correction unit 3 corrects the transmission signal such that the level of the transmission signal is multiplied by the distortion correction coefficient. The correction unit 3 outputs the corrected transmission signal (corrected signal). In the example of FIG. 1, the correction unit 3 is a multiplier 31. In this case, the multiplier 31 multiplies the transmission signal by the distortion correction coefficient, to correct the transmission signal.

The correction unit 3 may include an adder, a subtracter, and a divider in place of the multiplier 31. In any case, the correction unit 3 corrects the transmission signal such that the level of the transmission signal is multiplied by the distortion correction coefficient.

The digital-to-analog converter 4 (hereinafter, referred to as a “DAC 4”) receives the corrected signal from the correction unit 3, as an input. The DAC 4 performs digital-to-analog conversion (DA conversion) on the received corrected signal. The DAC 4 outputs an analog signal generated through the DA conversion. Any type of DAC, such as a pulse width modulation type or a delta sigma type, may be used as the DAC 4.

A filter, an amplifier, a buffer, an attenuator, a mixer and the like (hereinafter, collectively referred to as a “filter or the like”) may be provided between the correction unit 3 and the DAC 4. In this case, predetermined signal processing is performed on the corrected signal in the filter and the like, and the DA conversion is performed on the processed signal by the DAC 4. Thus, the DAC 4 outputs the analog signal corresponding to the corrected signal.

The amplification circuit 5 receives the analog signal output from the DAC 4, as an input and amplifies the received analog signal. In the example of FIG. 1, the amplification circuit 5 is a power amplifier 51 (hereinafter, referred to as a “PA 51”).

FIG. 3 is a diagram showing the gain characteristics of the PA 51. In FIG. 3, a solid line depicts the general gain characteristics of the PA 51, and a broken line depicts a constant gain straight line. In general, when an input signal level (amplitude or power of the input signal) increases as shown in FIG. 3, distortion occurs in the gain of the PA 51, because the gain is not constant.

When it is assumed that the design value of the gain of the PA 51 is A, the actual gain is A′, the input signal is Sin, and the output signal is Sout, Sout=Sin×A′=Sin×A is satisfied in an area where the level of the input signal Sin is low. However, Sout=Sin×A′ # Sin×A is satisfied in an area where the level of the input signal Sin is high, and distortion occurs in the output signal Sout.

The distortion correction coefficient is a coefficient for correcting the distortion of the output signal Sout caused by such gain characteristics of the PA 51. When the distortion correction coefficient is set so as to be proportional to the reverse characteristics of the PA 51, that is, A/A′ and the input signal Sin of the PA 51 is previously multiplied by the distortion correction coefficient, Sout=Sin×(A/A′)×A′=Sin×A is satisfied. Accordingly, it is possible to compensate for the distortion of the output signal Sout.

In the example of FIG. 1, the amplification circuit 5 is the PA 51, but may be another amplification circuit capable of amplifying the analog signal. In any case, the distortion correction coefficient is set so as to be proportional to the reverse characteristics of the gain of the amplification circuit 5.

The filter and the like may be provided between the DAC 4 and the amplification circuit 5. In this case, predetermined signal processing is performed on the analog signal output from the DAC 4 in the filter and the like, and the processed signal is amplified by the amplification circuit 5. Thus, the amplification circuit 5 amplifies a signal corresponding to the analog signal output from the DAC 4.

The antenna 6 transmits a radio signal corresponding to the analog signal output from the amplification circuit 5. Thus, it is possible to wirelessly transmit the transmission signal.

The analog-to-digital converter 7 (hereinafter, referred to as an “ADC 7”) receives the output signal of the amplification circuit 5, as an input. The ADC 7 performs analog-to-digital conversion (AD conversion) on the received output signal of the amplification circuit 5. The ADC 7 outputs the digital signal generated through the AD conversion. An arbitrary type of ADC such as a flash type or a pipe line type may be used as the ADC 7.

The filter and the like may be provided between the amplification circuit 5 and the ADC 7. In this case, predetermined signal processing is performed on the output signal of the amplification circuit 5 in the filter and the like, and AD conversion is performed on the processed signal by the ADC 7. Thus, the ADC 7 outputs a digital signal corresponding to the output signal of the amplification circuit 5. In the following description, a signal path from the output signal of the correction unit 3 to the signal adjusting unit 8 is referred to as a feedback circuit. A signal path from the DAC 4 to the ADC 7 is included in the feedback circuit.

The signal adjusting unit 8 (hereinafter, referred to as an “adjustment unit 8”) receives the output signal of the ADC 7, as an input. The adjustment unit 8 compensates for the gain of the feedback circuit by using the received output signal of the ADC 7. That is, the adjustment unit 8 divides the output signal of the ADC 7 by the gain of the feedback circuit. The gains of the DAC 4, the amplification circuit 5 and the ADC 7 are included in the gain of the feedback circuit. When the filter and the like are provided on the feedback circuit, the gains of the filter and the like are included in the gain of the feedback circuit. The adjustment unit 8 outputs the digital signal (adjusted signal) compensating for the gains of any included elements.

The filter and the like may be provided between the ADC 7 and the adjustment unit 8. In this case, predetermined signal processing is performed on the output signal of the ADC 7 in the filter and the like, and the gain thereof is compensated for by the adjustment unit 8. Thus, the adjustment unit 8 may output an adjusted signal corresponding to the output signal of the ADC 7. As stated above, when the filter and the like are provided between the ADC 7 and the adjustment unit 8 or between the correction unit 3 and the DAC 4, the gains of the filter and the like are included in the gain of the feedback circuit.

The adjustment unit 8 compensates for phase delay or phase advance in the feedback circuit. When the phase of the output signal of the ADC 7 advances further than the phase of a delay stop signal, to be described below, the adjustment unit 8 delays the phase of the output signal of the ADC 7. When the phase of the output signal of the ADC 7 is later than the phase of the delay stop signal, the adjustment unit 8 advances the phase of the output signal of the ADC 7. Thus, the adjustment unit 8 adjusts the phase of the output signal of the ADC 7 to be equal to the phase of the delay stop signal.

The transmission signal timing control unit 9 (hereinafter, referred to as a “control unit 9”) receives the transmission signal as an input. The control unit 9 delays the received transmission signal, and outputs the delayed signal. In the following description, the transmission signal delayed by the control unit 9 is referred to as a delayed transmission signal. The control unit 9 delays the transmission signal such that the phase of the delayed transmission signal coincides with the phase of the adjusted signal. That is, the control unit 9 allows the sample times of the delayed transmission signal and the adjusted signal to coincide with each other. The control unit 9 includes, for example, a delay circuit.

The distortion correction coefficient candidate calculating unit 10 (hereinafter, referred to as a “calculation unit 10”) receives the adjusted signal from the signal adjusting unit 8, as an input, and receives the delayed transmission signal from the transmission signal timing control unit 9 as an input. The calculation unit 10 calculates a distortion correction coefficient candidate based on the adjusted signal and the delayed transmission signal. The distortion correction coefficient candidate is a candidate value of the distortion correction coefficient corresponding to the level of the transmission signal. Specifically, the calculation unit 10 outputs a quotient obtained by dividing the level of the adjusted signal by the level of the delayed transmission signal, as the distortion correction coefficient candidate.

In the example of FIG. 1, the calculation unit 10 is a divider 101. In this case, the divider 101 divides the adjusted signal by the delayed transmission signal, so that it is possible to calculate the distortion correction coefficient candidate. The calculation unit 10 may include an adder, a subtracter, and a multiplier instead of the divider 101. In any case, the calculation unit 10 outputs the quotient obtained by dividing the level of the adjusted signal by the level of the delayed transmission signal.

The address timing control unit 11 (hereinafter, referred to as a “control unit 11”) receives the address from the conversion unit 1 as an input. The control unit 11 delays the received address, and outputs the delayed address. In the following description, the address delayed by the control unit 11 is referred to as a delayed address. The control unit 11 delays the address such that the phase of the delayed address and the phase of the distortion correction coefficient candidate output from the calculation unit 9 coincide with each other. That is, the control unit 11 allows the sample times of the address and the distortion correction coefficient candidate to coincide with each other. The control unit 11 includes, for example, a delay circuit.

The distortion correction coefficient updating unit 12 (hereinafter, referred to as an “update unit 12”) receives the distortion correction coefficient candidate from the calculation unit 10, as an input, and receives the delayed address from the control unit 11, as an input. The update unit updates the distortion correction coefficient corresponding to the delayed address stored in the table 2 according to the determination result retained in the address completion determining unit 13. That is, when the determination result of “update” is retained in the address completion determining unit 13, the update unit 12 updates the distortion correction coefficient, and when the determination result of “no update” is retained in the address completion determining unit 13, the update unit does not update the distortion correction coefficient. A method of determining whether to update the distortion correction coefficient is described below.

When the determination result of “update” is retained in the address completion determining unit 13, the update unit 12 reads the distortion correction coefficient corresponding to the delayed address from the table 2. That is, the update unit 12 inputs the delayed address to the table 2, the table 2 outputs the distortion correction coefficient corresponding to the delayed address, and the output distortion correction coefficient is input to the update unit 12.

Subsequently, the update unit 12 calculates a new distortion correction coefficient based on the distortion correction coefficient candidate and the distortion correction coefficient read from the table 2. For example, the update unit 12 calculates an average value or a weighted average value of the distortion correction coefficient candidate and the read distortion correction coefficient, as the new distortion correction coefficient. It is possible to reduce the influence of quantization noise on the ADC 7 by calculating such a new distortion correction coefficient.

The update unit 12 writes the new distortion correction coefficient as the distortion correction coefficient corresponding to the delayed address. Thus, the distortion correction coefficient stored in the table 2 is updated to the new distortion correction coefficient.

The update unit 12 may write the distortion correction coefficient candidate as the new distortion correction coefficient corresponding to the delayed address without reading the distortion correction coefficient corresponding to the delayed address from the table 2. In this case, the distortion correction coefficient is updated to the distortion correction coefficient candidate.

The address completion determining unit 13 (hereinafter, referred to as a “determination unit 13”) receives the address of the transmission signal from the conversion unit 1, as an input. The determination unit 13 counts the number of times the address that is input, compares the counted value with a threshold, and determines whether to update the distortion correction coefficient stored in the table 2. The determination unit 13 determines an “update” when the counted value is equal to or less than the threshold, and determines as “no update” when the counted value is greater than the threshold. The determination unit 13 retains the determination result. The determination result retained by the determination unit 13 is input to the stop signal conversion unit 14.

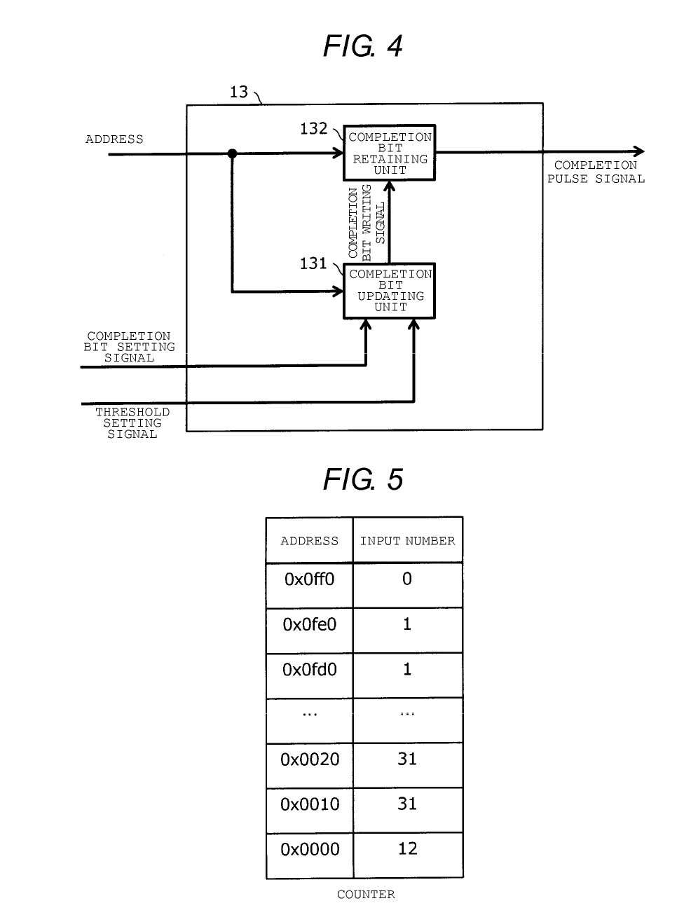

FIG. 4 is a diagram showing an example of the determination unit 13. As shown in FIG. 4, the determination unit 13 includes a completion bit updating unit 131, and a completion bit retaining unit 132.

The completion bit updating unit 131 (hereinafter, referred to as an “update unit 131”) receives the addresses from the conversion unit 1, as an input. The update unit 131 includes a counter that counts the number of times each address is input and retains the counted value. FIG. 5 is a diagram showing an example of the counter. In the example of FIG. 5, the counted value (input number) of an address of 0x0000 is 12. When the address of 0x0000 is newly input to the update unit 131, the counted value of the address of 0x0000 is 13.

The update unit 131 compares the counted value of the address input from the conversion unit 1 with a threshold, and determines whether to update the distortion correction coefficient of the address. The threshold is set for each address (each level) by a threshold setting signal input to the update unit 131.

When the counted value is greater than the threshold, the update unit 131 decides “no update”. When “no update” is decided, the update unit 131 generates a completion bit writing signal based on the received completion bit setting signal, and outputs the generated signal. Meanwhile, when the counted value is equal to or less than the threshold, the update unit 131 decides “update”. When “update” is decided, the completion bit updating unit 131 does not output the completion bit writing signal.

The counter is preferably reset by receiving a reset signal as an input.

The completion bit retaining unit 132 (hereinafter, referred to as a “retaining unit 132”) receives the address of the transmission signal from the conversion unit 1, as an input. When the update unit 131 determines as “no update”, the retaining unit 132 receives the completion bit writing signal from the update unit 131 as an input. The retaining unit 132 includes completion bits corresponding to the addresses.

Each completion bit retains the comparison result of the counted value of the corresponding address with the threshold, that is, the determination result of whether to update the distortion correction coefficient. The completion bit includes a 1-bit memory corresponding to each address, and has a value of 1 or 0. In the following description, it is assumed that each completion bit has an initial value of 0 and becomes 1 when the completion bit writing signal is input. A completion bit having a value of 0 indicates that the distortion correction coefficient of the corresponding address is updated, that is, the update is not completed. A completion bit having a value of 1 indicates that the distortion correction coefficient of the corresponding address is not updated, that is, the update is completed.

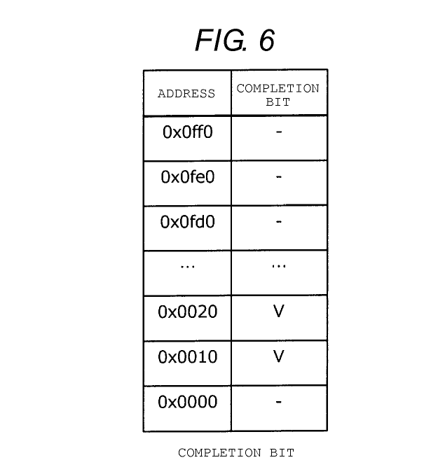

FIG. 6 is a diagram showing an example of the completion bit. In FIG. 6, “-(null value)” represents that the completion bit has a value of 0, and “V (Valid)” represents that the completion bit has a value of 1. In the example of FIG. 6, the completion bit of an address of 0x0010 is V. This corresponds to the determination result that the distortion correction coefficient of the address of 0x0010 is not updated (the update is completed). The completion bit of an address of 0x0ff0 has a null value. This corresponds to the determination result that the distortion correction coefficient of the address of 0x0ff0 is updated (the update is not completed). Thus, each completion bit retains the determination result.

When the address of the transmission signal from the conversion unit 1 is input, the retaining unit 132 refers to the value of the completion bit corresponding to this address. When the value of the completion bit is 1, that is, when the determination unit 131 determines that “no update” is performed on the distortion correction coefficient, the retaining unit 132 outputs a completion pulse signal. Meanwhile, when the value of the completion bit is 0, that is, when the determination unit 131 determines that “update” is performed on the distortion correction coefficient, the retaining unit 132 does not output the completion pulse signal.

The completion bit is preferably reset by turning off a power supply of the wireless communication device or receiving a reset signal as an input.

The stop signal conversion unit 14 (hereinafter, referred to as a “conversion unit 14”) receives the determination result retained by the determination unit 13, as an input. That is, when the determination unit 13 determines an “update”, the conversion unit 14 does not receive the completion pulse signal as an input, and when the determination unit 13 determines a “no update”, the conversion unit 14 receives the completion pulse signal as an input.

The conversion unit 14 converts the received completion pulse signal into the stop signal. The stop signal refers to a signal for stopping the calculations of the respective components of the wireless communication device. The conversion unit 14 outputs the converted stop signal.

The stop signal timing control unit 15 (hereinafter, referred to as a “control unit 15”) receives the stop signal from the conversion unit 14, as an input. The control unit 15 delays the received stop signal, and outputs the delayed signal. The stop signal delayed by the control unit 15 is referred to as a delayed stop signal.

The delayed stop signal is input to at least one of the ADC 7, the signal adjusting unit 8, the control unit 9, the calculation unit 10, the control unit 11, and the update unit 12. The component to which the delayed stop signal is input stops a calculation process. The control unit 15 delays the stop signal such that the phase of the delayed stop signal and the phase of the input signal of the component that stops the calculation with the delayed stop signal coincide with each other. That is, the control unit 15 allows the sample times of the delayed stop signal and the input signal to coincide with each other. Accordingly, a delay time at which the stop signal is delayed is different depending on the component to which the delayed stop signal is input. The control unit 15 includes, for example, a delay circuit.

In the example of FIG. 1, the delayed stop signal is input to the signal adjusting unit 8, the calculation unit 10, and the update unit 12. As mentioned above, the sample time of the delayed stop signal input to the signal adjusting unit 8 coincides with the sample time of the output signal of the ADC 7. The sample time of the delayed stop signal input to the calculation unit 10 coincides with the sample time of the adjusted signal. The sample time of the delayed stop signal input to the update unit 12 coincides with the sample time of the distortion correction coefficient candidate. When the delayed stop signal is input, the signal adjusting unit 8, the calculation unit 10 and the update unit 12 stop the calculations and the respective units keep the outputs at the same level as the previous sample time.

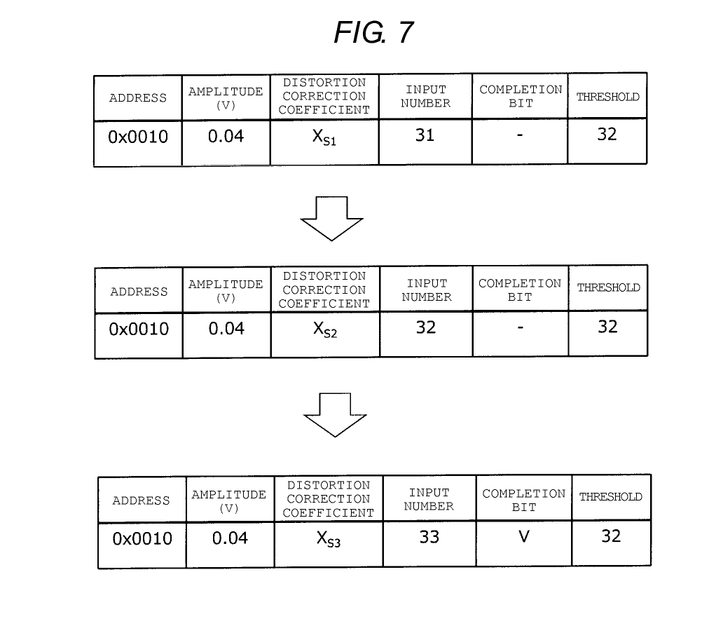

Next, the operation of the wireless communication device according to the present embodiment is described in detail with reference to FIG. 7. In the following description, it is assumed that transmission signals S₁ to S₃, each having an amplitude of 0.04 (V), are input. As shown in the top of FIG. 7, it is assumed that the address of the transmission signal having an amplitude of 0.04 (V) is 0x0010, a distortion correction coefficient is X_{S1}, an input number is 31, a completion bit is a null value, and a threshold is 32.

When the transmission signal S₁ is input to the wireless communication device, the conversion unit 1 outputs the address of 0x0010. The output address of 0x0010 is input to the table 2, the control units 9 and 11, and the determination unit 13. The table 2 outputs the distortion correction coefficient X_{S1} corresponding to the address of 0x0010. The correction unit 3 corrects the transmission signal S₁ using the distortion correction coefficient X_{S1}, and outputs the corrected signal. The DAC 4 performs DA conversion on the corrected signal, and outputs an analog signal corresponding to the corrected signal. The amplification circuit 5 amplifies the analog signal, and outputs the amplified signal. Thus, a radio signal corresponding to the transmission signal S₁ is transmitted from the antenna 6. The above process is referred to as a transmission process.

Similar to the above transmission process, the wireless communication device performs the following determination process.

First, when the address of 0x0010 is input, the retaining unit 132 refers to the completion bit of the address of 0x0010. Since the completion bit has a null value, the retaining unit 132 does not output the completion pulse signal. This corresponds to the determination result of “update”.

When the address of 0x0010 is input, the update unit 131 increases the counted value corresponding to the address of 0x0010 by 1. Thus, the input number of the address of 0x0010 becomes 32. Since the input number is equal to or less than the threshold, the update unit 131 does not output the completion bit writing signal. Accordingly, the completion bit of the address of 0x0010 of the retaining unit 132 is maintained at the null value.

As stated above, when the retaining unit 132 does not output the completion pulse signal, a process of updating the distortion correction coefficient is performed based on the transmission signal S₁ after the transmission process is ended. The updating process is as follows.

First, the output signal of the amplification circuit 5 is input to the ADC 7. The ADC 7 performs AD conversion on the output signal, and outputs the converted signal as a digital signal. The adjustment unit 8 compensates for the gain and phase of the digital signal, and outputs the adjusted signal. The calculation unit 10 calculates a distortion correction coefficient candidate X_{S1} based on the adjusted signal and the delayed transmission signal, and outputs the calculated candidate. The update unit 12 receives the delayed address as an input, and refers to the table 2. Since the delayed address is 0x0010, the update unit 12 obtains the distortion correction coefficient X_{S1} of the address of 0x0010. The update unit 12 calculates a new distortion correction coefficient X_{S2} based on the distortion correction coefficient X_{S1} and the distortion correction coefficient candidate, and writes the calculated new coefficient in the table 2. Thus, the distortion correction coefficient of the address of 0x0010 is updated to X_{S2}.

For example, regarding the distortion correction coefficient X_{S2}, X_{S2}=(X_{S1}+X_{S1})/2 may be satisfied, and X_{S2}=X_{S1} may be satisfied. Alternatively, regarding the distortion correction coefficient X_{S2}=(X_{S1}+31×X_{S1})/32 may be satisfied. In this case, the updated distortion correction coefficient is an average value of the distortion correction coefficient candidates calculated in all the updating processes.

Through the determination process and the updating process, as shown in the middle of FIG. 7, the distortion correction coefficient of the address of 0x0010 is Xₛ₂, the input number is 32, and the completion bit has a null value.

When the transmission signal S₂ is input to the wireless communication device, the transmission process and the determination process are performed again. The transmission process is the same as the above-described transmission process, and a radio signal corresponding to the transmission signal S₂ is transmitted from the antenna 6. The determination process that is concurrently performed with the transmission process is as follows.

First, when the address of 0x0010 is input, the retaining unit 132 refers to the completion bit of the address of 0x0010. Since the completion bit has a null value, the retaining unit 132 does not output the completion pulse signal. This corresponds to the determination result of “update” and is the same as the above-described determination process.

Meanwhile, when the address of 0x0010 is input to the update unit 131, the input number of the address of 0x0010 is 33. Since the input number is greater than the threshold, the update unit 132 outputs the completion bit writing signal. Thus, the completion bit of the address of 0x0010 of the retaining unit 132 is V. At a time when the input number is greater than the threshold, the counter of the retaining unit 132 is preferably ended.

Since the determination result is “update”, the process of updating the distortion correction coefficient based on the transmission signal S₂ is performed after the transmission process is ended. The updating process is the same as the above-described updating process, and the distortion correction coefficient of the address of 0x0010 is updated to X_{S3}.

Through the determination process and the updating process, as shown in the bottom of FIG. 7, the distortion correction coefficient of the address of 0x0010 is X_{S3}, the input number is 33, and the completion bit is V.

When the transmission signal S₃ is input to the wireless communication device, the transmission process and the determination process are performed again. The transmission process is the same as the above-described transmission process, and a radio signal corresponding to the transmission signal S3 is transmitted from the antenna 6. The determination process that is concurrently performed with the transmission process is as follows.

First, when the address of 0x0010 is input, the retaining unit 132 refers to the completion bit of the address of 0x0010. Since the completion bit is now V, the retaining unit 132 outputs the completion pulse signal. This corresponds to the determination result of “no update”.

Subsequently, the conversion unit 14 converts the completion pulse signal into the stop signal, and outputs the stop signal. The control unit 15 delays the stop signal, and outputs the delayed stop signal. The delayed stop signal is input to the adjustment unit 8, the calculation unit 10, and the update unit 12.

Since the adjustment unit 8, the calculation unit 10, and the update unit 12 stop the calculations by using the delayed stop signal, the updating process based on the transmission signal S₃ is not performed. Accordingly, the distortion correction coefficient of the address of 0x0010 is maintained at X_{S3}. Even through the transmission signal having an amplitude of 0.04 (V) is input to the wireless communication device, the process of updating the distortion correction coefficient is not performed.

As described above, the wireless communication device according to the present embodiment counts the input number of the transmission signal for each level, updates the distortion correction coefficient when the input number is equal to or less than the threshold, and does not update the distortion correction coefficient when the input number is greater than the threshold. That is, the number of times the distortion correction coefficient is updated is limited to be the threshold or less. When the update number and the threshold coincide with each other, the updating process is regarded as being completed, and the updating process is not performed.

As mentioned above, by limiting the number of times the process of updating the distortion correction coefficient is performed to be the threshold or less, the distortion correction coefficient is adjusted to be an appropriate value according to the temperature characteristics of the amplification circuit 5. Thus, it is possible to reduce the distortion of the output signal, and it is possible to reduce the power consumption of the wireless communication device.

Since the determination process is performed based on the input number of the transmission signal, it is possible to concurrently perform the transmission process and the determination process. Accordingly, when the updating process is not performed, it is possible to stop the calculations of the adjustment unit 8, the calculation unit 10 and the update unit 12 before the updating process is started. Thus, it is possible to further reduce the power consumption of the wireless communication device.

### Second Embodiment

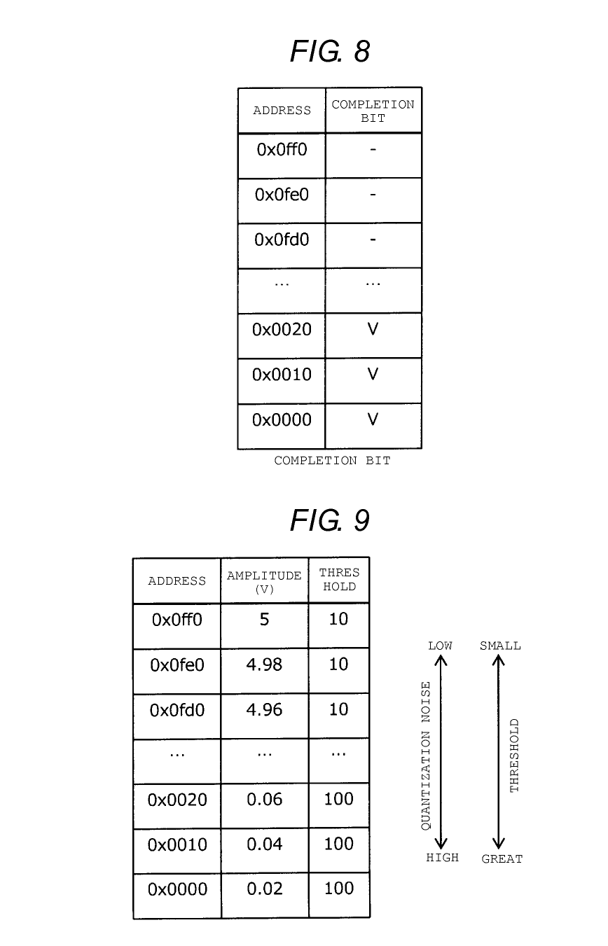

Next, a wireless communication device according to a second embodiment is described with reference to FIG. 8. FIG. 8 is a diagram showing an example of an initial state of a completion bit according to the present embodiment. In the present embodiment, an initial value of a completion bit of which the level is equal to or less than a predetermined value is previously set as 1, as shown in FIG. 8. Accordingly, even though a transmission signal of which the level is equal to or less than a predetermined value is input, the updating process is not performed.

When the amplification circuit 5 is the PA 51, the distortion of the output signal Sout is small in the area where the level of the input signal Sin is low, as stated above. For this reason, when the level of the transmission signal is low, the transmission signal is corrected using the design value of the distortion correction coefficient without updating the distortion correction coefficient, little distortion occurs in the output signal of the PA 51.

Accordingly, according to the present embodiment, it is possible to further reduce the power consumption of the wireless communication device while reducing the distortion of the output signal of the PA 51.

### Third Embodiment

Next, a wireless communication device according to a third embodiment is described with reference to FIG. 9. FIG. 9 is a diagram showing an example of a threshold set for each level in the present embodiment. In the present embodiment, as shown in FIG. 9, the lower the level is, the greater the threshold is set, and the higher the level is, the smaller the threshold is set. Accordingly, the lower the level of the transmission signal is, the greater the update number is, and the higher the level of the transmission signal is, the smaller the update number is.

In general, the lower the level of the transmission signal is, the higher the quantization noise is due to the ADC 7. The higher the level of the transmission signal is, the lower the quantization noise is due to the ADC 7. In the present embodiment, the higher the quantization noise (the lower the level) of the transmission signal is, the greater the update number of the distortion correction coefficient is. Thus, it is possible to efficiently reduce the influence of the quantization noise, and reduce the distortion of the output signal.

### Fourth Embodiment

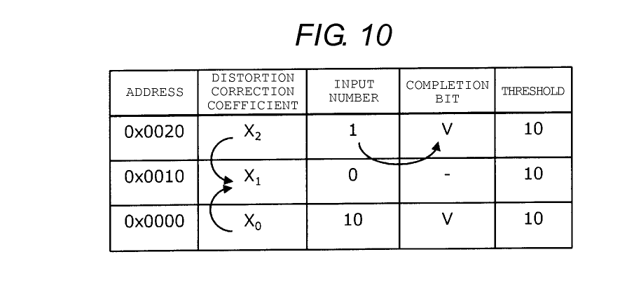

Next, a wireless communication device according to a fourth embodiment is described with reference to FIG. 10. FIG. 10 is a diagram showing examples of a table 2, a counter and a completion bit at the time of ending packet transmission. The packet mentioned herein refers to a unit of data transmission including a plurality of transmission signals. The time at which the packet transmission is ended may be a time at which the transmission of one packet is ended, may be a time at which the transmission of a predetermined number of packets is ended, or may be a time at which the transmission of a specific packet is ended.

In the first embodiment, the completion bit having the level with which the input number (update number) is equal to the threshold is set as V and it is determined that the updating of the distortion correction coefficient set for the level is completed. However, in the present embodiment, at the time of ending the packet transmission, when the completion bit has a level with which the input number is equal to or greater than 1, the completion bit is set as V, and it is determined that the updating of the distortion correction coefficient set for the level is completed.

In the example of FIG. 10, the input number of an address of 0x0020 is 1, and a threshold is 10. In this case, in the first embodiment, since the input number is equal to or less than the threshold, the completion bit of the address of 0x0020 is set as a null value. Accordingly, the distortion correction coefficient X₂ set for the address of 0x0020 is updated.

However, in the present embodiment, since the input number of the address of 0x0020 is equal to or greater than 1, the completion bit is set as V. Accordingly, the distortion correction coefficient set for the address of 0x0020 is not updated.

The distortion correction coefficient of each level is updated at least one time by setting the completion bit as described above. Accordingly, it is possible to calculate the distortion correction coefficient according to the temperature characteristics of the amplification circuit 5. Since the updating of the distortion correction coefficient is completed with the input number which is less than the threshold, it is possible to further reduce the power consumption of the wireless communication device.

In the present embodiment, the distortion correction coefficient set for the level with which the input number is 0 at the time of ending the packet transmission is interpolated based on the distortion correction coefficient set for another level with which the completion bit is set as V.

In the example of FIG. 10, the distortion correction coefficient X₁ of the address of 0x0010 in which the input number is 0 is interpolated based on the distortion correction coefficient X₀ of the address of 0x0000 or the distortion correction coefficient X₂ of the address of 0x0020.

Since the distortion correction coefficient is interpolated as described above, it is possible to set even a distortion correction coefficient that is not updated one time to be a value according to the temperature characteristics of the amplification circuit 5.

A method of interpolating the distortion correction coefficient may be arbitrarily selected, and may be a linear interpolation method, a polynomial interpolation method, or a spline interpolation method.

The disclosure is not limited to the embodiments, and may be embodied by changing the components thereof without departing from the gist thereof in an implementation stage. Various inventions are possible by appropriately combining a plurality of components disclosed in the embodiments. For example, several components may be removed from all the components described in the embodiments. Moreover, components described in different embodiments may be appropriately combined with one another.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wireless communication device comprising:
a memory that contains a table that stores a plurality of distortion correction coefficients which are respectively set for different amplitude levels of an input transmission signal;
a correction unit to which the input transmission signal and one of the distortion correction coefficients are input, the correction unit configured to generate a corrected transmission signal based on the input transmission signal and one of the distortion correction coefficients that are input thereto;
a digital-to-analog converter connected to the correction unit to generate an analog signal from the corrected transmission signal;
a power amplifier configured to amplify the analog signal;
an analog-to-digital converter connected to the power amplifier to convert the amplified signal into a digital signal;
a calculation unit configured to calculate a distortion correction coefficient candidate based on the input transmission signal and the digital signal; and
an update unit configured to update the distortion correction coefficient stored in the table based on the distortion correction coefficient candidate,
wherein the update unit updates the distortion correction coefficient stored in the table when the number of times the transmission signal is input to the correction unit is equal to or less than a predetermined threshold, and does not update the distortion correction coefficient when the number of times the transmission signal is input to the correction unit is greater than the threshold.

2. The device according to claim 1,
wherein when the number of times the transmission signal is input to the correction unit is greater than the threshold, the calculation unit stops calculation of the distortion correction coefficient candidate.

3. The device according to claim 1, further comprising:
an adjustment unit that compensates for at least one of a gain, phase advance, and phase delay in a feedback circuit including a signal path from the analog-to-digital converter to the digital-to-analog converter.

4. The device according to claim 1, further comprising:
a determination unit that includes a counter configured to count the number of times the transmission signal is input to the correction unit, and a retaining unit that retains the comparison result of the counted number with the threshold.

5. The device according to claim 1,
wherein the update unit does not update the distortion correction coefficient when an amplitude level of the input transmission signal is equal to or less than a predetermined level.

6. The device according to claim 1,
wherein the threshold is set in inverse proportion to an amplitude level of the input transmission signal.

7. The device according to claim 1,
wherein the threshold is one.

8. The device according to claim 1,
wherein a distortion correction coefficient for a first amplitude level is interpolated based on a distortion correction coefficient for a second amplitude level.

9. A gain-correction device comprising:
a correction unit to which a transmission signal and a correction coefficient are input, the correction unit configured to generate a corrected transmission signal based on the transmission signal and the correction coefficient;
a memory storing a coefficient table that contains the correction coefficient used by the correction unit to correct the transmission signal;
a power amplifier configured to generate an amplified signal from an analog signal corresponding to the corrected transmission signal;
a signal adjusting unit that operates in one of first and second modes, the signal adjusting unit generating an adjusted signal based on a digital signal corresponding to the amplified signal and the transmission signal when operating in the first mode and not generating an output when operating in the second mode;
a calculation unit that operates in one of first and second modes, the calculation unit generating a correction coefficient candidate based on the adjusted signal when operating in the first mode and not generating an output when operating in the second mode;
an update unit that operates in one of first and second modes, the update unit updating the correction coefficient in the coefficient table based on the candidate correction coefficient when operating in the first mode and not generating an output when operating in the second mode; and
a stop signal generating unit configured to generate a stop signal based on a number of updates to the correction coefficient in the coefficient table, the stop signal being supplied to the signal adjusting unit, the calculation unit, and the update unit to cause the signal adjusting unit, the calculation unit, and the update unit to operate in the second mode.

10. The device according to claim 9, wherein the coefficient table includes a correction coefficient for each power or amplitude level of the transmission signal.

11. The device according to claim 9, further comprising:
a determination unit configured to track the number of updates to the correction coefficient in the coefficient table.

12. The device according to claim 11, wherein the determination unit maintains a count of each update performed by the update unit and compares the count against a threshold.

13. The device according to claim 12, wherein the determination unit includes a counter that tracks the number of updates to the correction coefficient in the coefficient table and is configured to compare the number tracked by the counter to a threshold to determine whether or not the stop signal should be generated by the stop signal generating unit.

14. The method according to claim 13, wherein the stop signal is generated if the number of updates equals or exceeds one.

15. A method for operating a wireless communication device, the method comprising the steps of:
(a) generating a corrected transmission signal based on an input transmission signal and a correction coefficient that is stored in a coefficient table in memory;
(b) amplifying an analog signal corresponding to the corrected transmission signal;
(c) generating an adjusted signal based on a digital signal corresponding to the amplified signal and the input transmission signal, and a correction coefficient candidate based on the adjusted signal; and
(d) updating the correction coefficient in the coefficient table based on the candidate correction coefficient,
wherein the steps (c) and (d) are performed until the correction coefficient has been updated a threshold number of times.

16. The method according to claim 15, further comprising:
determining a number of updates to the correction coefficient in the coefficient table; and
generating a stop signal based on the number of updates to the correction coefficient in the coefficient table, the stop signal causing the steps (c) and (d) to be no longer performed.

17. The method according to claim 16, wherein the stop signal is generated if the number of updates equals or exceeds one.

18. The method according to claim 15, wherein if the input transmission signal has a high amplitude or power, the threshold has a first value and if the input transmission signal has a low amplitude or power, the threshold has a second value, the first value being substantially less than the second value.

19. The method according to claim 15, wherein the steps (c) and (d) are no longer performed when the correction coefficient has been updated the threshold number of times.

20. The method according to claim 15, further comprising:
transmitting the amplified signal through an antenna.
